(19) United States
(12) Patent Application Publication
(10) Pub. No.: US 2014/0333286 A1
(43) Pub. Date: Nov. 13, 2014

(54) LOAD PANEL BRANCH CIRCUIT MONITOR EMPLOYING AN INTELLIGENT CURRENT SENSOR MODULE

(71) Applicant: EATON CORPORATION, CLEVELAND, OH (US)

(72) Inventors: RONGSHENG WANG, CORAOPOLIS, PA (US); CHRISTOPHER D. WELLS, MCMURRAY, PA (US); MICHAEL P. KING, PITTSBURGH, PA (US); TIMOTHY FREDRIC THOMPSON, PITTSBURGH, PA (US); MICHAEL CHARLES DADIAN, FLETCHER, NC (US)

(73) Assignee: EATON CORPORATION, CLEVELAND, OH (US)

(21) Appl. No.: 13/888,626

(22) Filed: May 7, 2013

(51) Int. Cl. G01R 19/25

(52) U.S. Cl. CPC G01R 19/25
USPC 324/113; 324/114

(57) ABSTRACT

A branch circuit monitor is for a load panel inputting a number of line voltages and including a plurality of currents. The branch circuit monitor includes a processor component having a plurality of digital interfaces and is structured to receive a plurality of first digital values from each of the digital interfaces; and a plurality of metering mechanisms external to the processor component. Each of the metering mechanisms is structured to: communicate with a corresponding one of the digital interfaces, convert analog values from the number of line voltages and a plurality of the currents to a plurality of second digital values, determine a plurality of digital energy values from the second digital values, and transmit the second digital values and the digital energy values to the corresponding one of the digital interfaces.

### BACKGROUND

1. Field

The disclosed concept pertains generally to branch circuit monitors and, more particularly, to branch circuit monitors for load panels. The disclosed concept further pertains to load panels that include a branch circuit monitor.

2. Background Information

It is known to deliver hundreds of analog signal conductors from current transformers (CTs) to a central processing unit (CPU) of a load panel branch circuit monitor (BCM) for processing by a single digital signal processor (DSP) and the CPU. A number of problems are associated with this prior proposal. For example, relatively expensive multi-conductor ribbon cables and connectors (e.g., up to 50-pins) are employed to deliver hundreds of analog signal conductors over the requisite distance creating reliability and assembly difficulties. Calibration is relatively very difficult to handle since burden resistors are within the BCM at the CPU and are physically separated from the various CTs. As a result, better than 1% accuracy and better metering are not cost effective due to the added component cost and complexity necessary to manage calibration of separate sensing and processing assemblies using multiplexing of relatively many analog signals. Also, an open circuit clamping diode is needed for each CT, which adds to the cost.

The root of these problems is the centralization of the metering in the prior BCM, which requires all current and voltage analog signals to be wired to a CPU board.

There is room for improvement in branch circuit monitors.

There is also room for improvements in load panels which include a branch circuit monitor.

### SUMMARY

These needs and others are met by various aspects of the disclosed concept. As one aspect of the disclosed concept, a branch circuit monitor is for a load panel inputting a number of line voltages and including a plurality of currents. The branch circuit monitor comprises: a processor component comprising a plurality of digital interfaces, the processor component being structured to receive a plurality of first digital values from each of the digital interfaces; and a plurality of metering mechanisms external to the processor component, each of the metering mechanisms being structured to: communicate with a corresponding one of the digital interfaces, convert analog values from the number of line voltages and a plurality of the currents to a plurality of second digital values, determine a plurality of digital energy values from the second digital values, and transmit the second digital values and the digital energy values to the corresponding one of the digital interfaces.

As another aspect of the disclosed concept, a load panel inputs a number of line voltages and includes a plurality of currents. The load panel comprises: an enclosure enclosing a number of main circuit breakers and a plurality of branch circuit breakers; and a branch circuit monitor comprising: a processor component comprising a plurality of digital interfaces, the processor component being structured to receive a plurality of first digital values from each of the digital interfaces; and a plurality of metering mechanisms external to the processor component, each of the metering mechanisms being structured to: communicate with a corresponding one of the digital interfaces, convert analog values from the number of line voltages and a plurality of the currents to a plurality of second digital values, determine a plurality of digital energy values from the second digital values, and transmit the second digital values and the digital energy values to the corresponding one of the digital interfaces.

As another aspect of the disclosed concept, a branch circuit monitor is for a load panel including a plurality of currents. The branch circuit monitor comprises: a processor component comprising a plurality of digital interfaces, the processor component being structured to receive a plurality of first digital values from each of the digital interfaces; and a plurality of metering mechanisms external to the processor component, each of the metering mechanisms being structured to: communicate with a corresponding one of the digital interfaces, convert analog values from a plurality of the currents to a plurality of second digital values, determine a plurality of digital energy values from the second digital values and a number of digital voltage values, and transmit the second digital values and the digital energy values to the corresponding one of the digital interfaces.

### BRIEF DESCRIPTION OF THE DRAWINGS

A full understanding of the disclosed concept can be gained from the following description of the preferred embodiments when read in conjunction with the accompanying drawings in which:

FIG. 1 is a block diagram of a branch circuit monitor for processing inputs from a plurality of intelligent metering modules in accordance with embodiments of the disclosed concept.

FIG. 2 is a relatively more detailed block diagram of the branch circuit monitor of FIG. 1.

FIG. 3A is a plan view of one of the intelligent metering modules of FIG. 1.

FIG. 3B is a vertical elevation view of one of the intelligent metering modules of FIG. 1.

FIG. 4A is a block diagram of a load panel including a main circuit breaker, a plurality of branch circuit breakers, and a branch circuit monitor for processing inputs from two intelligent metering modules in accordance with another embodiment of the disclosed concept.

FIG. 4B is a block diagram of a load panel including two main circuit breakers, a plurality of branch circuit breakers, and a branch circuit monitor for processing inputs from four intelligent metering modules in accordance with another embodiment of the disclosed concept.

FIG. 5 is a schematic diagram in block form of an intelligent metering module in accordance with another embodiment of the disclosed concept.

FIG. 6 is a schematic diagram of one of the analog interface circuits of FIG. 5 including a current transformer, burden resistors and a filter circuit.

FIG. 7 is a block diagram of a branch circuit monitor for processing inputs from a plurality of intelligent metering modules in accordance with another embodiment of the disclosed concept.

### DESCRIPTION OF THE PREFERRED EMBODIMENTS

As employed herein, the term “number” shall mean one or an integer greater than one (i.e., a plurality).

As employed herein, the term “processor” shall mean a programmable analog and/or digital device that can store, retrieve, and process data; a computer; a controller; a workstation; a personal computer; a microprocessor; a microcontroller; a microcomputer; a digital signal processor; a central processing unit; a central data aggregation unit; a mainframe computer; a mini-computer; a server; a networked processor; or any suitable processing device or apparatus.

As employed herein, the statement that two or more parts are “connected” or “coupled” together shall mean that the parts are joined together either directly or joined through one or more intermediate parts.

As employed herein, the term “load panel” shall mean a load center, a panelboard, a circuit breaker panel, or any suitable enclosure enclosing or housing a number of electrical switching apparatus for a number of branch or other load circuits.

The disclosed concept is described in association with a three-phase load panel including a number of three-phase main circuit breakers and a plurality of single-phase branch circuit breakers, although the disclosed concept is applicable to a wide range of load panels and to circuit breakers having any number of phases or poles.

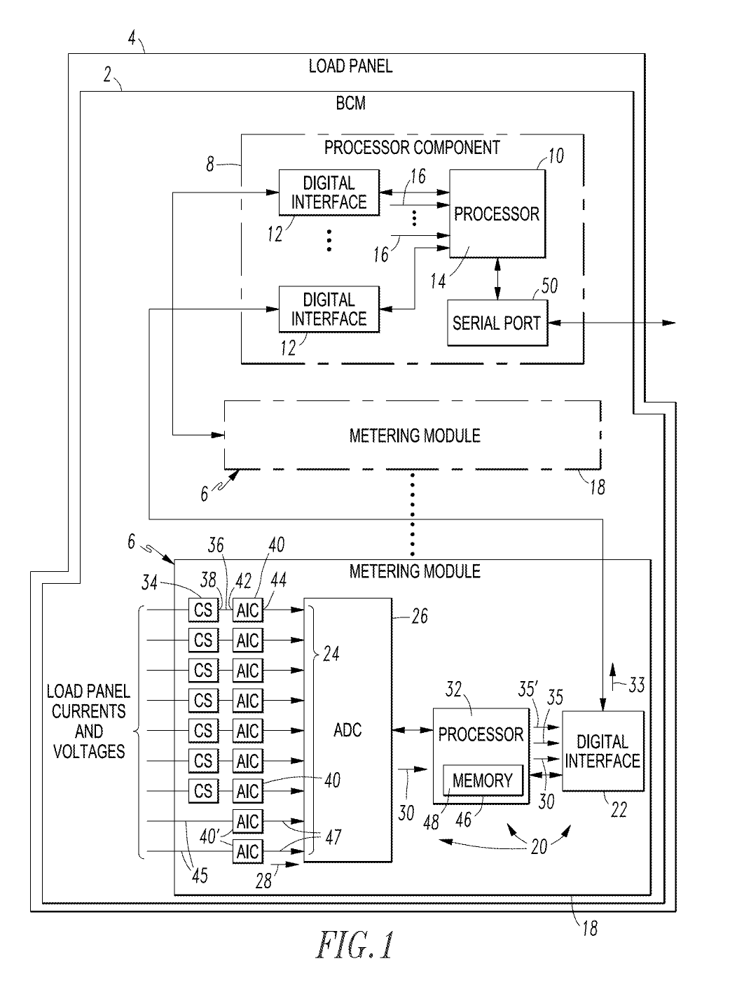

FIG. 1 shows a branch circuit monitor (BCM) 2 for a load panel 4 for processing inputs from a plurality of intelligent metering modules (e.g., without limitation, strips) 6. The BCM 2 includes a processor component 8 (e.g., without limitation, a central data aggregation unit) having a processor 10 including a plurality of digital interfaces 12, and a first routine 14 structured to receive a plurality of first digital values 16 from each of the digital interfaces 12. Each of the intelligent metering modules 6 includes a substrate, such as the example printed circuit board (PCB) 18, a processor component 20 including a digital interface 22, a plurality of analog inputs 24, an analog to digital converter (ADC) mechanism 26 structured to convert a plurality of analog values 28 from the analog inputs 24 to a plurality of second digital values 30, and a second routine 32 structured to transmit a plurality of third digital values 33 from the digital interface 22. A plurality of current sensors (CSs) 34 (e.g., without limitation, a plurality of current transformers (CTs)) are mounted on or coupled to the PCB 18. Alternatively, any suitable current sensor (e.g., without limitation, a Hall-effect sensor) can be employed. Each of the CSs 34 is structured to sense a current flowing in a conductor (e.g., 103 of FIG. 6) of the load panel 4 and output a corresponding analog signal 36 to an output 38. A plurality of analog interface circuits (AICs) 40,40′ are mounted on the PCB 18. The analog interface circuits 40 each have an input 42 electrically connected to the output 38 of a corresponding one of the CSs 34 and an output 44 electrically connected to a corresponding one of the analog inputs 24 of the processor component 20. A number of the AICs 40′ (e.g., without limitation, filter and/or resistive divider) input a number of voltages 45 and output a number of analog signals 47 to a corresponding number of the analog inputs 24.

Each of the AICs 40 includes a number of burden resistors (not shown) for applications where the CSs 34 are CTs.

Non-limiting examples of the digital interfaces 12,22 include serial digital interfaces, such as RS-485, RS-422, RS-232, LonWorks®, Profibus DP, SMARTWIRE-DT®, DeviceNet™ and CANopen.

The processor component 20 is structured to determine a number of digital energy (E) values 35 (e.g., E=∫P=∫(I*V)) from the second digital values 30, which correspond to the number of voltages (V) and to the sensed current (I) flowing in the conductor of the load panel 4 for each of the CSs 34. The third digital values 33 include the second digital values 30 and the number of digital energy values 35.

The processor component 20 can also determine a number of digital power (P) values 35′ (e.g., P=(I*V)) from the second digital values 30, which correspond to the number of voltages (V) and to the sensed current (I) flowing in the conductor of the load panel 4 for each of the CSs 34. The third digital values 33 can also include the number of digital power values 35′.

The digital interface 22 is coupled for communication with a corresponding one of the digital interfaces 12. The second routine 32 transmits the third digital values 33 from the digital interface 22 to the corresponding one of the digital interfaces 12. The first routine 14 receives the third digital values 33 as at least some of the first digital values 16.

The digital interfaces 12,22 can be wired or wireless serial digital interfaces.

### Example 1

The processor component 20 preferably includes a memory 46 that stores calibration data 48 for the CSs 34. The memory 46 also stores configuration pairing information (e.g., which current(s) and voltage(s) correspond to each circuit breaker), computed energy values, load current polarity, and a wide range of other values.

For example and without limitation, the calibration data 48 can include voltage calibration values, gain and offset calibration values, the relationship (phase) between current and voltage, and variances of voltage references, analog to digital converters and/or clock circuits. Preferably, all calibration values for power and energy measurement are self-contained in the metering modules 6. The output of the metering modules 6 is calibrated digital data, thereby eliminating the transfer of raw, un-calibrated data between metering sub-assemblies. Hence, the calibration is local to the metering modules 6 and is not split among separate assemblies within a metering system.

### Example 2

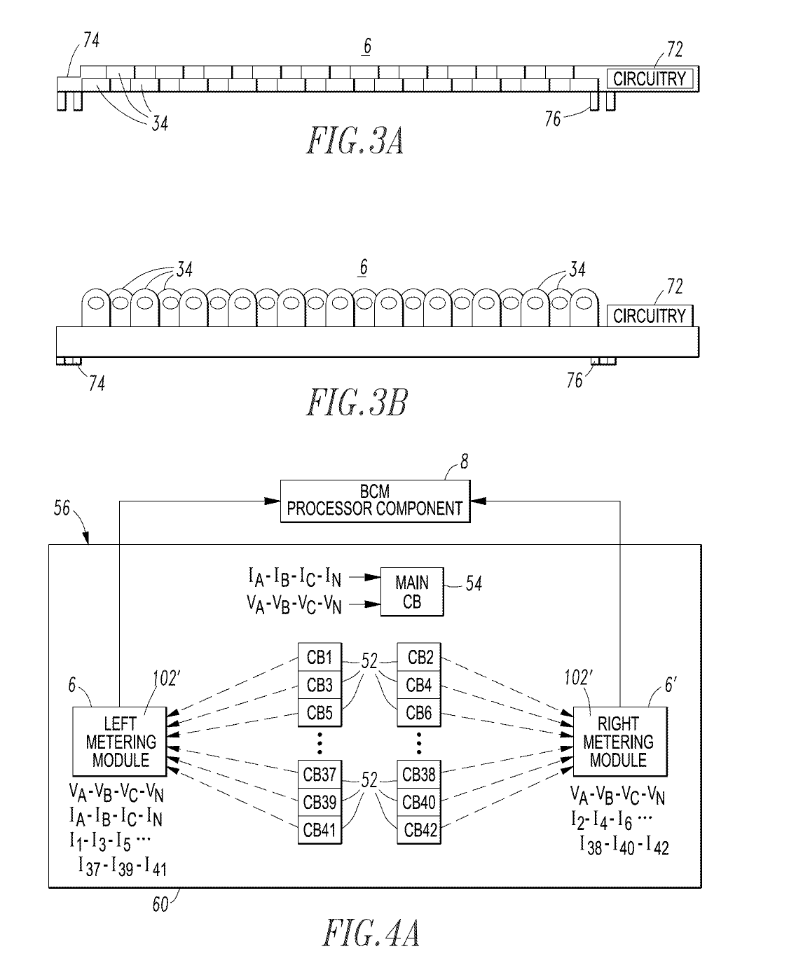

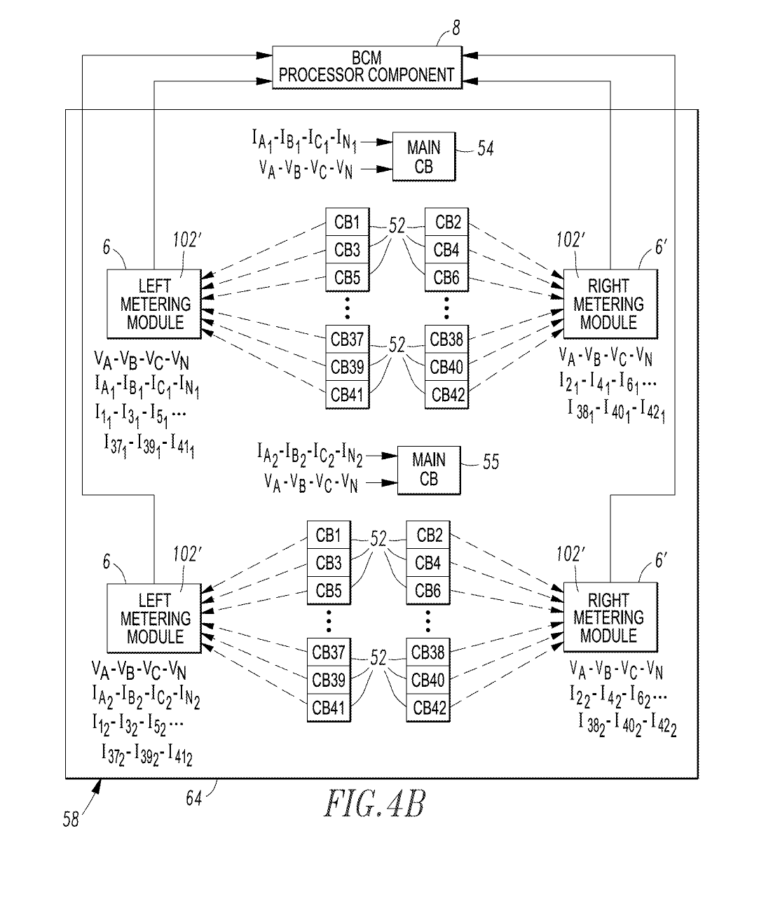

The CSs 34 can be solid core CTs 34 (FIGS. 3A-3B) or 102 (FIG. 6) and/or split core CTs 102′ (FIGS. 4A-4B).

### Example 3

The processor 10 preferably includes a serial port 50 structured to provide network communications.

### Example 4

As will be discussed below in connection with FIGS. 4A and 4B, the current sensed by the CSs 34 (FIG. 1) can be a load current of a branch circuit breaker 52 and a line current of a main circuit breaker 54,55 of a load panel 56,58.

### Example 5

Also, the current sensed by the CSs 34 can be a neutral current of the main circuit breakers 54,55 of the respective load panels 56,58.

### Example 6

As shown in FIG. 4A, the load panel 56 includes an enclosure 60 enclosing the one main circuit breaker 54 and a plurality (e.g., without limitation, up to 42) branch circuit breakers 52. The load panel 56 also includes the BCM processor component 8 and two intelligent metering modules 6,6′. The intelligent metering modules 6′ may be the same as or substantially similar to the module 6, although they need not monitor the line and neutral currents (I_{A},I_{B},I_{C},I_{N}) of the main circuit breaker 54.

As shown in FIG. 4B, the load panel 58 includes an enclosure 64 enclosing the two main circuit breakers 54,55, and a plurality (e.g., without limitation, up to 84) branch circuit breakers 52. The load panel 58 also includes the BCM processor component 8 and four intelligent metering modules 6,6,6′,6′.

### Example 7

The load panels 56,58 can be load centers, panelboards or circuit breaker panels.

### Example 8

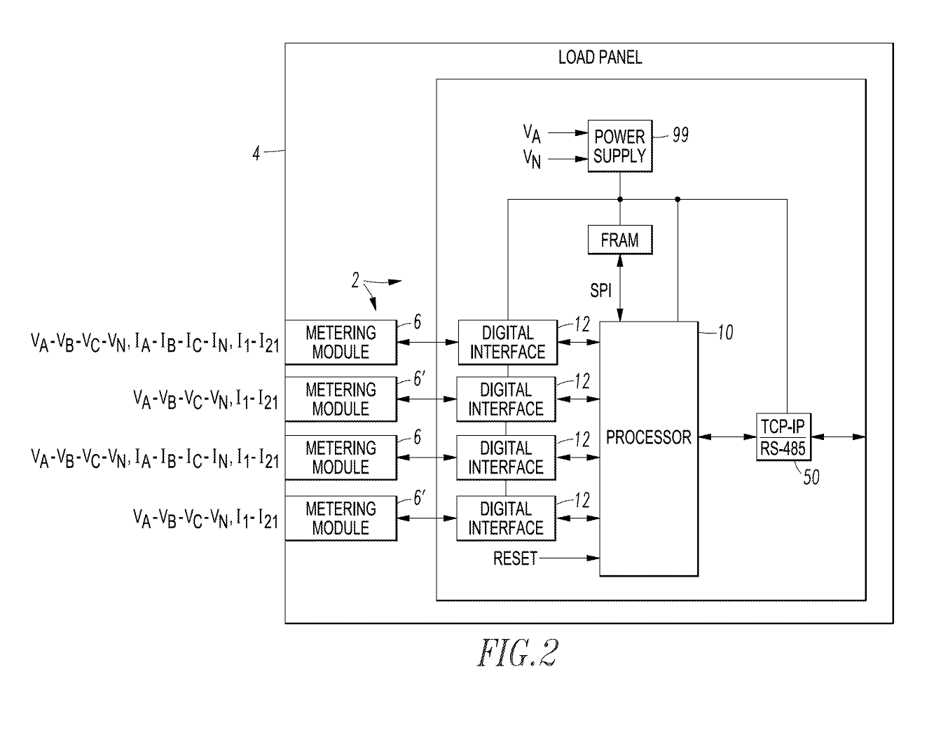

As shown in FIGS. 4A and 4B, the BCM processor component 8 is mounted external to the respective enclosures 60 and 64. In those examples, the CSs 34 (FIG. 1) of the metering modules 6,6′ are split core CTs, in order that the BCM processor component 8 and the metering modules 6,6′ can be added to an existing load panel, which may not have sufficient internal space for the BCM processor component 8, and which may have existing load wiring already electrically connected to the branch circuit breakers 52. Preferably, as will be discussed below in connection with Example 11, the entire BCM 2 is mounted internal to one of the enclosures 60 or 64 (as is shown with the load panel 4 of FIGS. 1 and 2), and the CSs 34 (FIG. 1) are solid core CTs.

The solid core CTs are typically factory installed on the PCB 18 of the metering modules 6,6′, which are mounted inside the load panel enclosures 60 or 64 along with the BCM processor component 8 (e.g., as is shown with the BCM 2 and the load panel 4 of FIGS. 1 and 2).

Alternatively, the split core CTs are mounted in an existing load panel (e.g., for a retrofit application) and their secondary winding (not shown) is electrically connected to the PCB 18 of the metering modules 6,6′, which can be mounted internal (as shown) or external (not shown) to the load panel enclosures 60 or 64. Except for the secondary winding, the split core CTs are not mounted on the PCB 18 of the metering modules 6,6′. This permits these split core CTs to be used in a retrofit application, since they can be worked into the constraints of an existing running power distribution system without disturbing the load conductors. The electrical connection of the secondary wiring to the PCB 18 is important since this unifies the calibration of the metering modules 6,6′ with split core CTs. As a result, all of the analog variables are part of the monolithic metering modules 6,6′, all calibration is done as one unit, and, thus, the output of fully calibrated digital data (third digital values 33 of FIG. 1) is possible.

### Example 9

FIG. 2 shows is a relatively more detailed view of the BCM 2 of FIG. 1. The metering modules 6 input I_{A},I_{B},I_{C},I_{N} of the main circuit breakers (e.g., 54,55 of FIG. 4B), while the metering modules 6′ do not. Typically, there are two kinds of load panels (e.g., 56 of FIG. 4A and 58 of FIG. 4B), which accommodate either 42 branch circuit breakers 52 or 84 branch circuit breakers 52. Each of four metering modules 6,6′ inputs currents (I₁-I₂₁) from up to 21 branch circuits. Therefore, for 42 branch circuit breakers 52 (FIG. 4A), there are a total of 42+4=46 current channels with two metering modules 6. Similarly, for 84 branch circuit breakers 52 (FIG. 4B), there are a total of (42+4)*2=92 current channels with four metering modules 6,6′. In addition, the main circuit breaker line voltages (V_{A},V_{B},V_{C}) can also be monitored and reported. V_{N} is the neutral conductor and serves as the common reference for V_{A},V_{B},V_{C}.

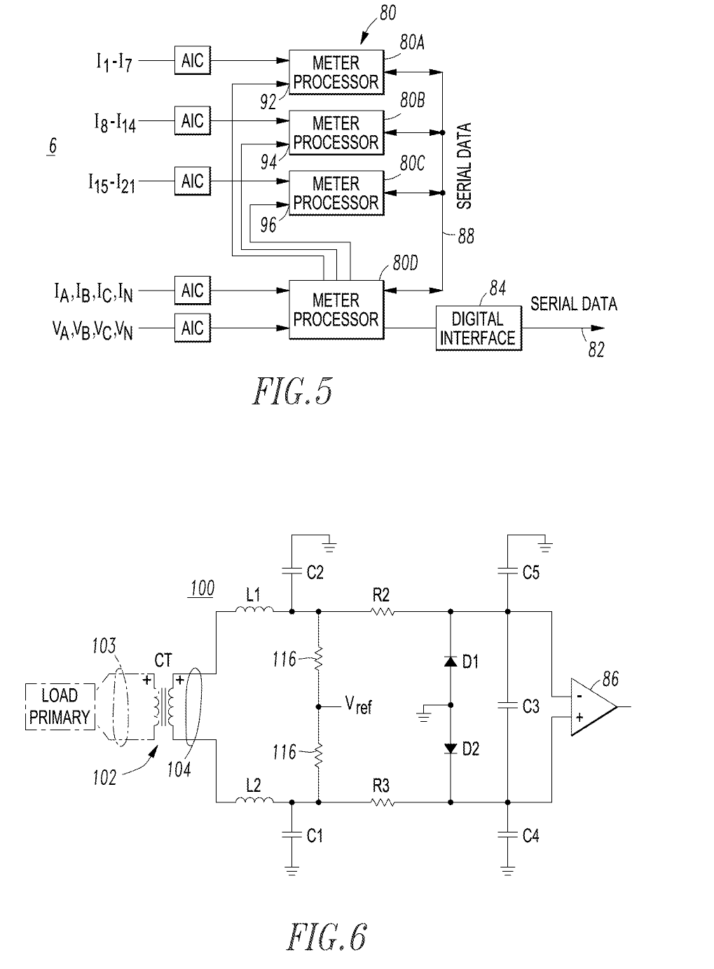

As will be described in greater detail, below, in connection with FIG. 5, the intelligent metering modules 6,6′, which are remote from the BCM processor 10 (FIG. 2), input and convert line and load current and line voltage analog signals to digital signals and output the same on a serial channel to the BCM processor 10. The BCM processer 10 preferably serves as a network communication center by employing the serial port 50 (FIGS. 1 and 2) to provide network communications, such as for example and without limitation, TCP-IP protocols (e.g., without limitation, TCP Modbus®) or RS-485 protocol (e.g., without limitation, Modbus®; other suitable communication protocols) plus some other functions (e.g., without limitation, an I/O function). The de-centralization of the hardware architecture as provided by the intelligent metering modules 6,6′ permits the BCM processer 10 to provide additional functionality. As a result, a plurality (not shown) of the BCMs 2 can be installed as part of a TCP network (not shown).

The disclosed BCM 2 can monitor, for example, up to 84 circuit breaker branch circuits and up to eight main circuit breaker line and neutral circuits, report the corresponding voltages, currents, power quality, alarm status and the energy allocation. The BCM 2 can report through the serial port 50, for example, the main circuit breaker voltages (V_{A},V_{B},V_{C}), the main circuit breaker line currents (I_{A},I_{B},I_{C},I_{N}), power (W), energy (WHr), power factor (PF), and up to 84 branch circuit currents, which all come from the metering modules 6,6′ external to the processor 10.

Applications for this technology include load panels having relatively many circuit breakers. For example, today, far less than 1% of known load panels are monitored, including those, for example and without limitation, in residences.

All digital signal processing of analog values is within the example intelligent metering modules 6,6′. Only the resulting digital data is serially delivered to the BCM processor 10.

The routine 32 (FIG. 1) is structured to transmit the digital values 33 from the digital interface 22 to the corresponding one of the BCM digital interfaces 12 (FIG. 2). For example and without limitation, the connection between the metering module 6 and the BCM processor component 8 can be an RJ45 cable (not shown) containing RS-485/RS-422 conductors (not shown) as well as DC power from a BCM power supply 99 (FIG. 2).

### Example 10

FIGS. 3A and 3B show the intelligent metering module 6, which includes 21 example CSs 34 and additional circuitry 72 as will be discussed, below, in connection with FIGS. 5 and 6. Connectors 74,76 are respectively provided for receiving the load panel line voltages and for interfacing with a corresponding one of the BCM digital interfaces 12. In this example, solid core CTs 34 are shown.

### Example 11

In the example of FIGS. 1 and 2, the BCM 2 and the intelligent metering modules 6,6′ are internal to example load panel 4. Alternatively, as shown in FIGS. 4A and 4B, the BCM processor component 8 can be external to the enclosures 60 and 64 of the respective load panels 56 and 58. The current sensed by the CSs 34 (FIGS. 1, 3A and 3B) can be line and neutral currents of the main circuit breakers 54,55 of the load panels 56,58, and/or the load currents of the branch circuit breakers 52.

The analog inputs 24 (FIG. 1) include, for example and without limitation, inputs for up to seven currents (I₁-I₇), which can either be branch circuit load currents or main circuit breaker line/neutral currents, and inputs for up to four voltages (V_{A},V_{B},V_{C},V_{N}), which can be branch circuit breaker line/neutral voltages or main circuit breaker line/neutral voltages. Each of the current analog inputs 24 is input by a corresponding example CT/burden resistor/interface (I/F) circuit 100 (FIG. 6), which includes a CT 102. In the example of FIG. 5, the CTs 102 (FIG. 6) are mounted on the PCB 18 (FIG. 1).

### Example 12

FIG. 4A shows that the load panel 56 includes the single main circuit breaker 54, up to 42 branch circuit breakers 52, and the BCM processor component 8 for processing inputs from two intelligent metering modules 6,6′, each of which interfaces up to 21 of the up to 42 branch circuit breakers 52. The metering module 6 also inputs a plurality of line currents and a neutral current of the main circuit breaker 54.

### Example 13

FIG. 4B shows that the load panel 58 includes the two main circuit breakers 54,55, up to 84 branch circuit breakers 52, and the BCM processor component 8 for processing inputs from four intelligent metering modules 6,6′, each of which interfaces up to 21 of the up to 84 branch circuit breakers 52. The two metering modules 6 also input a plurality of line currents and a neutral current of the main circuit breakers 54,55. The two metering modules 6′ can differ in that they need not input the line and neutral currents of the main circuit breakers 54,55.

### Example 14

FIG. 5 shows the intelligent metering module 6, it being understood that the intelligent metering module 6′ (FIG. 2) can be substantially the same as or similar to the metering module 6. A number of metering functions are all provided by a monolithic assembly. Voltage and current measurements are combined in order that calibration (e.g., without limitation, gain adjustments; phase relationships between voltage and current signals) can be contained within the modules 6,6′ and not be split. Also, power measurements can be integrated into energy locally, thereby eliminating polling problems with a central aggregating CPU board (not shown). The modules 6,6′ provide the analog measurements and output calibrated digital data.

The example metering module 6 includes four metering processors 80 (e.g., without limitation, an MSP430™ ultra-low power 16-bit microcontroller marketed by Texas Instruments Incorporated of Dallas, Tex.), although any suitable number or type of metering processors can be employed. In this example, three of the four metering processors 80A,80B,80C are “slaves” and one of the four metering processors 80D is a “master”, although any suitable arrangement of multiple metering processors can be provided. The three example slave metering processors 80A,80B,80C input and convert branch load currents (I₁-I₇, I₈-I₁₄ and I₁₅-I₂₁). The example master metering processor 80D inputs and converts main circuit breaker currents (I_{A},I_{B},I_{C},I_{N}) and voltages (V_{A},V_{B},V_{C},V_{N}), and also collects serial digital data from the other three slave metering processors 80A,80B,80C and outputs serial digital data 82 on the digital interface 84 to the central data aggregation unit or processor component 8 (FIG. 1).

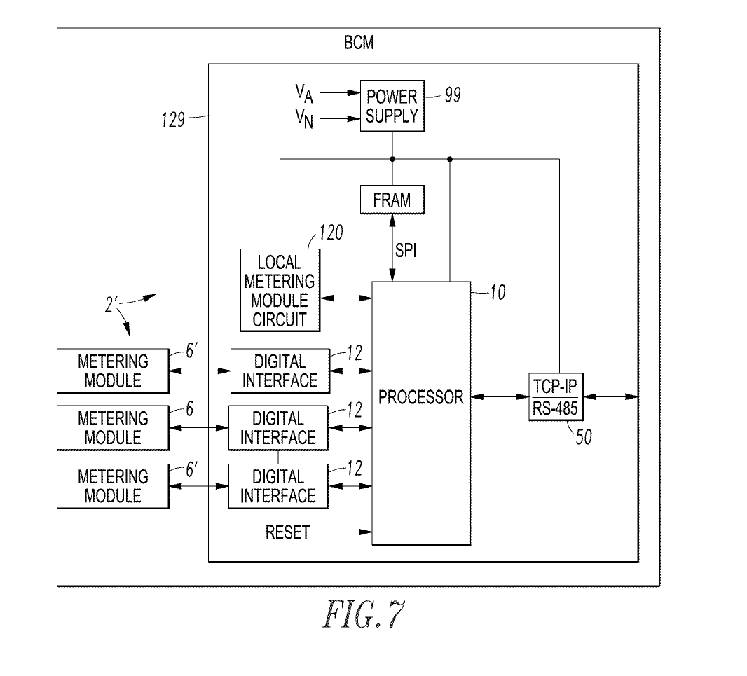

Other functions that can be performed by the example metering processors 80 include: (1) measure current and voltage simultaneously; (2) apply calibration factors to these measurements for gain and phase, and perform a high pass filter to eliminate DC offsets; (3) associate the proper phase voltage to each load channel (e.g., by configuration); (4) associate the proper current flow polarity to each load channel (e.g., by configuration); (5) multiply current times voltage to provide power; (6) integrate current, voltage and power into RMS values over a suitable time interval for each load channel; (7) integrate power into energy for each load channel; (8) derive other metering data, such as, for example and without limitation, frequency; (9) provide all of this metering data to the processor 10 of the central data aggregation unit 8; (10) accept configuration information from the aggregator processor 10; (11) accept calibration and functional control commands from the aggregator processor 10; (12) accept firmware upgrades from the aggregator processor 10; (13) provide product and production identification information to the aggregator processor 10; (14) provide meter module health status to the aggregator processor 10; and/or (15) accept power to operate from the aggregator's power supply 99 (FIG. 7).

The example metering processors 80 include seven Sigma Delta differential inputs 86 (one is shown in FIG. 6) for metering purposes. These work simultaneously and determine power (i.e., voltage×current=power) in real time, thereby eliminating most data skew issues. The example master metering processor 80D performs the mains voltage measurement and shares it with the three example slave metering processors 80A,80B,80C in real time, sample set by sample set, over a suitable digital interface 88 (e.g., without limitation, an SPI broadcast bus with synch controls). In this manner, the effect of multiple metering processors 80 measurement loading voltage channels is eliminated.

The example master metering processor 80D is the interface/gateway between the aggregator processor 10 (FIG. 1) and the other three example slave metering processors 80A,80B,80C. The digital interface 84 between the master metering processor 80D and the aggregator processor 10 can be, for example and without limitation, RS-485 or RS-422 or any suitable hardware serial digital interface.

The master metering processor 80D also exchanges data with the other three slave metering processors 80A,80B,80C over the digital interface 88 using a chip select 92,94,96 for each respective slave metering processor 80A,80B,80C. Over this digital interface 88, calibration and related system commands, initialization data and firmware upgrades are sent to the slave metering processors 80A,80B,80C. During normal operation, metering data is brought up through the digital interface 88 and the master metering processor 80D to the aggregator processor 10. Each slave metering processor 80A,80B,80C performs all of the metering functions per branch circuit channel, and obtains its configuration and controls from the master metering processor 80D.

As shown in FIG. 6, the current transformer 102 has a secondary current loop 104 from its secondary winding that drives two example burden resistors 116. The accuracy of the current transformer turns ratio, burden resistor and the metering analog circuitry are all on the same module 6 or 6′ (FIG. 2). As such, all of the current measurement calibration variables can be captured in one place relative to the voltage measurement circuitry.

FIG. 6 also shows that various filter elements providing filtering for electromagnetic interference (EMI) and fault overload considerations can be provided. Any influence these filter elements may have on the resulting measurement due to leakage currents and similar impedance loading is also be captured locally by the modules 6,6′. The filter elements include the series ferrite beads L1,L2, common mode capacitors C1,C2,C4,C5, and capacitor C3. The example burden resistors 116 are split and center tapped to the midpoint (V_{ref}) of the analog power rails. This provides a balanced differential input to the corresponding differential input 86 of a corresponding one of the metering processors 80. The resistors R2,R3 limit the current during EMI or fault overload conditions. The common mode capacitors C1,C2 shunt relatively high frequency EMI and limit RF emission. The common mode capacitors C4,C5 deal with imbalances of the analog to digital converter (not shown, but see the analog to digital converter (ADC) mechanism 26 of FIG. 1). The capacitor C3 forms an RC filter with the resistors R2 and R3. The capacitors C3,C4,C5 relative to the resistors R2,R3 provide common mode and differential anti-aliasing filtering and help source the flying capacitor front end of the modules 6,6′. The diodes D1,D2 are clamps to ground, which may be needed by certain metering processors. Typically, however, electrostatic discharge (ESD) protection circuits are simple diodes with current limited to a suitable value such that diode clamps are not needed. Preferably, such ESD protection circuits have a suitable low leakage such that the leakage is not significant relative to analog signal measurement.

The metering module 6 (FIG. 1) includes the substrate, such as the example PCB 18. The processor component 20 includes the digital interface 22 and executes the routine 32 and transmits the digital values 30 from the digital interface 22, which is coupled for communication with the corresponding one of the BCM digital interfaces 12.

The example embodiment of FIG. 6 can be employed for either a solid core CT or a split core CT. The latter is for a preexisting load panel with no BCM when the load panel was manufactured and the BCM processor component 8 is installed external to the load panel.

### Example 15

Although the digital values 30 (FIG. 1) are discussed in terms of the main circuit breaker voltages (V_{A},V_{B},V_{C}), the main circuit breaker line currents (I_{A},I_{B},I_{C},I_{N}) and the branch circuit breaker load currents (I₁-I₇), the disclosed concept is applicable to metering mechanisms that also calculate and report power (W), energy (WHr) and power factor (PF).

### Example 16

FIG. 7 shows another BCM 2′, which is somewhat similar to the BCM 2 of FIG. 2. The main differences are that one of the metering modules 6 (e.g., for the main circuit breaker) is included with the BCM 2′ as a local metering module circuit 128, the corresponding digital interface 22 (FIG. 1) and digital interface 12 (FIG. 2) are eliminated, and the local metering module circuit 128 and the BCM 2′ share the same PCB 129.

### Example 17

The BCM 2′ of FIG. 7 can input up to 25 current values from up to 21 branch circuit breakers and a first main circuit breaker (not shown), and input up to 67 current values from the metering modules 6′,6,6′ from up to 63 branch circuit breakers and a second main circuit breaker (not shown). The BCM 2′ forms an intelligent master metering module, which collects data from its local metering module circuit 128 and also collects data from three other slave intelligent metering modules 6′,6,6′.

### Example 18

Although the BCMs 2,2′ disclosed herein convert a number of line voltages 45 to a number of corresponding digital values for use in determining power and/or energy values, the BCMs 2,2′ can alternatively employ a number of predetermined digital voltage values (e.g., without limitation, predetermined digital values corresponding to conventional 110 V or 120 V line voltages).

The disclosed concept provides metering within each metering module in order that only the digital data needs to be delivered to the BCM processor 10 by just a few conductors. This provides a fundamental change to and the improvement of the BCM.

The disclosed concept employs an intelligent metering module, such as an example metering module 6, in which digital signal processing is provided. The resulting digital data is serially sent to the corresponding processor 10 of the BCM 2 employing a relatively few digital serial data communication lines, which replace 50 pin-connectors and 50-pin ribbon cables for hundreds of analog signal conductors, 84 TVS bi-directional diodes for protecting corresponding CTs, and external calibration data storage. Instead, where each CT needs to be calibrated, the calibration data can be stored in the metering module (e.g., in the memory 46 of FIG. 1) for the processor component 20 to read. Since each burden resistor 116 (FIG. 6) and the processors 80 (FIG. 5) are all on the same intelligent metering module 6, the calibration process is much easier, which reduces the manufacturing cost and the product cost with improved accuracy.

Furthermore, much better metering (e.g., without limitation, 0.5% accuracy or better) is possible due to cost saving and de-centralization of the hardware architecture. Moreover, the intelligent metering module 6 and the BCM processor component 8 can be manufactured and tested independently to create various types of BCMs and/or other products, which is not possible with known prior BCMs.

The disclosed concept can be applied to all kind of CTs including, for example, solid core, split core, relatively low-current rated CTs, and relatively high-current rated CTs, as opposed to only 100 A solid core CTs. Known BCMs are limited to one type of solid core CT, since the different CTs have different burden resisters and, thus, require different BCM CPU boards.

The disclosed concept employs far fewer conductors, no ribbon cables and no relatively large connectors. As a result, assembly is relatively fast, clean and easy. Energy accuracy is improved from about 1%-3% to about 0.5%, especially for relatively low currents. Calibration is relatively much easier, better and lower in cost. Manufacturing cost is significantly less.

While specific embodiments of the disclosed concept have been described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of the disclosed concept which is to be given the full breadth of the claims appended and any and all equivalents thereof

What is claimed is:

1. A branch circuit monitor for a load panel inputting a number of line voltages and including a plurality of currents, said branch circuit monitor comprising:
a processor component comprising a plurality of digital interfaces, said processor component being structured to receive a plurality of first digital values from each of said digital interfaces; and
a plurality of metering mechanisms external to said processor component, each of said metering mechanisms being structured to:
communicate with a corresponding one of said digital interfaces,
convert analog values from the number of line voltages and a plurality of said currents to a plurality of second digital values,
determine a plurality of digital energy values from the second digital values, and
transmit the second digital values and the digital energy values to the corresponding one of said digital interfaces.

2. The branch circuit monitor of claim 1 wherein said processor component is a central data aggregation unit for said load panel.

3. The branch circuit monitor of claim 1 wherein each of said metering mechanisms comprises a plurality of current sensors structured to sense a plurality of said analog values from said currents, and a number of analog interface circuits structured to provide a number of said analog values from said number of line voltages.

4. The branch circuit monitor of claim 3 wherein each of said metering mechanisms further comprises a memory storing current sensor calibration data for said current sensors.

5. The branch circuit monitor of claim 3 wherein said current sensors are selected from the group consisting of a solid core current transformer and a split core current transformer.

6. The branch circuit monitor of claim 1 wherein said processor component further comprises a serial port structured to provide network communications.

7. The branch circuit monitor of claim 1 wherein said currents are selected from the group consisting of a load current of a branch circuit breaker and a line current of a main circuit breaker of said load panel.

8. The branch circuit monitor of claim 1 wherein one of said currents is a neutral current of a main circuit breaker of said load panel.

9. The branch circuit monitor of claim 1 wherein said each of said metering mechanisms comprises a plurality of metering processors communicating over a digital interface; and wherein one of said metering processors inputs first serial digital data from a number of said metering processors and outputs second serial digital data on a digital interface to the corresponding one of said digital interfaces.

10. The branch circuit monitor of claim 9 wherein said currents are selected from the group consisting of a load current of a branch circuit breaker and a line current of a main circuit breaker of said load panel; and wherein said plurality of analog inputs receive at least some of said load current, said line current and the number of the line voltages of the main circuit breaker.

11. The branch circuit monitor of claim 10 wherein said plurality of metering processors are four metering processors; wherein each of three of said four metering processors inputs seven load currents for seven branch circuit breakers and a plurality of the line voltages of the main circuit breaker; and wherein another one of said four metering processors inputs a plurality of line currents of the main circuit breaker and the number of the line voltages of the main circuit breaker.

12. The branch circuit monitor of claim 11 wherein said load panel includes up to 84 branch circuit breakers and up to two three-phase main circuit breakers; and wherein said processor component is structured to monitor up to 6 line voltages of the two main circuit breakers and to monitor as said currents up to 84 load currents and up to 8 line currents.

13. The branch circuit monitor of claim 10 wherein a first one of said metering mechanisms includes three of said metering processors to input up to 21 load currents for up to 21 branch circuit breakers of said load panel; and wherein a second one of said metering mechanisms includes three of said metering processors to input up to 21 load currents for up to 21 branch circuit breakers and another one of said metering processors to input up to four line currents of the main circuit breaker.

14. The branch circuit monitor of claim 3 wherein said metering mechanisms further comprise a number of burden resistors for each of said current sensors.

15. The branch circuit monitor of claim 1 wherein said each of said metering mechanisms is further structured to determine a plurality of digital power values from the second digital values, and transmit the digital power values to the corresponding one of said digital interfaces.

16. A load panel inputting a number of line voltages and including a plurality of currents, said load panel comprising:
an enclosure enclosing a number of main circuit breakers and a plurality of branch circuit breakers; and
a branch circuit monitor comprising:
a processor component comprising a plurality of digital interfaces, said processor component being structured to receive a plurality of first digital values from each of said digital interfaces; and
a plurality of metering mechanisms external to said processor component, each of said metering mechanisms being structured to:
communicate with a corresponding one of said digital interfaces,
convert analog values from the number of line voltages and a plurality of said currents to a plurality of second digital values,
determine a plurality of digital energy values from the second digital values, and
transmit the second digital values and the digital energy values to the corresponding one of said digital interfaces.

17. The load panel of claim 16 wherein said number of main circuit breakers is two main circuit breakers; and wherein each of two of said metering mechanisms inputs a plurality of line currents and a neutral current of a corresponding one of said two main circuit breakers.

18. The load panel of claim 16 wherein said number of main circuit breakers is one main circuit breaker; wherein said plurality of branch circuit breakers is up to 42 branch circuit breakers; wherein each of two of said metering mechanisms interfaces up to 21 of said up to 42 branch circuit breakers; and wherein one of said metering mechanisms inputs a plurality of line currents and a neutral current of said main circuit breaker.

19. The load panel of claim 16 wherein said number of main circuit breakers is two main circuit breakers; wherein said plurality of branch circuit breakers is up to 84 branch circuit breakers; wherein each of four of said metering mechanisms interfaces up to 21 of said up to 84 branch circuit breakers; and wherein each of two of said metering mechanisms inputs a plurality of line currents and a neutral current of a corresponding one of said two main circuit breakers.

20. The load panel of claim 16 wherein said load panel is a load center or panelboard.

21. The load panel of claim 16 wherein each of said metering mechanisms comprises a plurality of current sensors structured to sense a plurality of said analog values from said currents, and a number of analog interface circuits structured to provide a number of said analog values from said number of line voltages; wherein said processor component is mounted external to said enclosure; and wherein said current sensors are split core current transformers.

22. The load panel of claim 16 wherein each of said metering mechanisms comprises a plurality of current sensors structured to sense a plurality of said analog values from said currents, and a number of analog interface circuits structured to provide a number of said analog values from said number of line voltages; wherein said branch circuit monitor is mounted internal to said enclosure; and wherein said current sensors are solid core current transformers.

23. The load panel of claim 16 wherein said each of said metering mechanisms is further structured to determine a plurality of digital power values from the second digital values, and transmit the digital power values to the corresponding one of said digital interfaces.

24. A branch circuit monitor for a load panel including a plurality of currents, said branch circuit monitor comprising:
a processor component comprising a plurality of digital interfaces, said processor component being structured to receive a plurality of first digital values from each of said digital interfaces; and
a plurality of metering mechanisms external to said processor component, each of said metering mechanisms being structured to:
communicate with a corresponding one of said digital interfaces,
convert analog values from a plurality of said currents to a plurality of second digital values,
determine a plurality of digital energy values from the second digital values and a number of digital voltage values, and
transmit the second digital values and the digital energy values to the corresponding one of said digital interfaces.
